(19) United States
(12) Patent Application Publication
(10) Pub. No.: US 2006/0097287 A1
(43) Pub. Date: May 11, 2006

(54) Semiconductor device and manufacturing method thereof

(75) Inventor: Ichiro Mizushima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba, Tokyo (JP)

(21) Appl. No.: 11/319,534

(22) Filed: Dec. 29, 2005

Related U.S. Application Data
(62) Division of application No. 10/459,532, filed on Jun. 12, 2003.

(30) Foreign Application Priority Data
Jun. 13, 2002 (JP) 2002-172628

(51) Int. Cl. H01L 29/94; H01L 21/8244

(52) U.S. Cl. 257/204; 257/296; 438/238; 257/E27.092

(57) ABSTRACT

A semiconductor device of this invention comprises a semiconductor substrate, a plurality of memory regions provided on the semiconductor substrate, the plurality of memory regions having the same structure, and functional region provided on the semiconductor substrate, the functional region including a different function from the memory.

### CROSS-REFERENCE TO RELATED APPLICATIONS

This application is based upon and claims the benefit of priority from the prior Japanese Patent Application No. 2002-172628, filed Jun. 13, 2002, the entire contents of which are incorporated herein by reference.

### BACKGROUND OF THE INVENTION

1. Field of the Invention

The present invention relates to a semiconductor device including a memory region and a functional region having a different function from the memory and a manufacturing method thereof and more particularly to an LSI embedded with DRAM adopting a trench capacitor as its memory cell and a manufacturing method thereof.

2. Description of Related Art

The LSI has been produced in the form of a DRAM, logic LSI and the like as a chip having a different function since before. In recent years, to meet requirement for higher performance, LSIs called system LSI or embedded LSI have been manufactured by embedding LSIs having different functions on a single chip.

This kind of the LSI is produced with multiple types each in a small quantity, different from conventional versatile DRAM or logic LSI which is expected to be manufactured in a large quantity with a single type and produced in a short period.

If manufacturing process is considered, a system LSI embedded with the DRAM and logic LSI (DRAM embedded LSI) costs high for its masking process because the mask differs depending on each product type, which is produced in a small quantity. For the reason, there is such a problem that the manufacturing cost is increased as compared to the versatile DRAM or the logic LSI.

Further, it takes a long time to produce a mask corresponding to the specification of each product type, thereby making it impossible to shorten the manufacturing period.

If the trench capacitor is employed as a capacitor which constitutes a DRAM's memory cell, etching condition needs to be determined for each product type because total area (occupied area) of the trench capacitor differs depending on each product type.

If the total area of the trench capacitor within a memory cell is different even if the depth and aspect of that trench capacitor which constitutes the memory cell, the etching condition for the trench differs. For the reason, the etching condition needs to be determined for each product type, thereby making it further impossible to shorten the manufacturing period.

### BRIEF SUMMARY OF THE INVENTION

A semiconductor device according to an aspect of the present invention comprises a semiconductor substrate; a plurality of memory regions provided on the semiconductor substrate, the plurality of memory regions having the same structure; and a functional region provided on the semiconductor substrate, the functional region including a different function from the memory.

A method of manufacturing a semiconductor device according to an aspect of the present invention comprises preparing a wafer on which predetermined steps of forming memories have been performed, the wafer including a plurality of memory regions having the same structure, performing steps subsequent to the predetermined steps of forming the memories on one region of the wafer, the one region including at least one of the plurality of memory regions and forming a functional region having a different function from a memory function on the one region; and cutting out the one region from the wafer.

A method of manufacturing a semiconductor device according to another aspect of the present invention comprises preparing a plurality of wafers on which predetermined steps of forming memories have been performed, the plurality of wafers including a plurality of memory regions respectively, structures of the plurality of memory regions of the plurality of wafers being equal each other and memory capacities of the plurality of memory regions of the plurality of wafers being different each other; selecting one wafer from the plurality of wafers; performing steps subsequent to the predetermined steps of forming the memories on one region of the selected wafer, the one region including at least one of the plurality of memory regions and forming a region having a different function from a memory function on the one region; and cutting out the one region from the selected wafer.

### BRIEF DESCRIPTION OF THE SEVERAL VIEWS OF THE DRAWING

FIGS. 1A to 1D are plan views showing a wafer according to an embodiment;

FIGS. 2A and 2B are diagrams showing a structure of DRAM region of the embodiment;

FIGS. 3A to 3J are sectional views showing a manufacturing process of the DRAM embedded LSI of the embodiment;

FIGS. 4A and 4B are diagrams showing a section of the DRAM embedded LSI of the embodiment;

FIG. 5 is a diagram for explaining problems in a manufacturing process of a conventional DRAM embedded LSI;

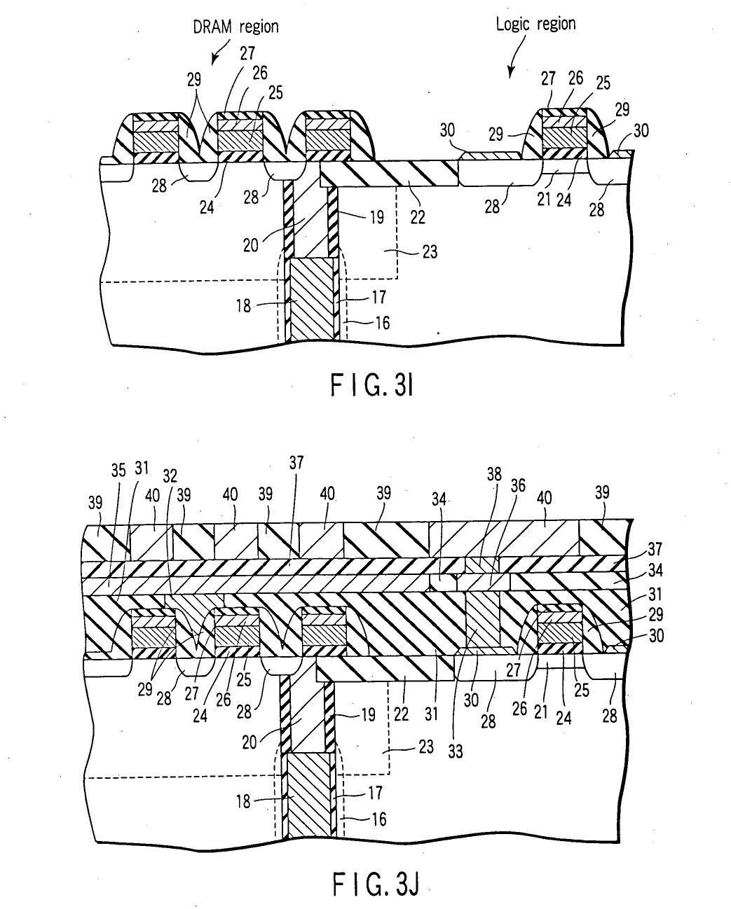

FIG. 6 is a diagram for explaining an effect of a manufacturing process of the DRAM embedded LSI of the embodiment;

FIG. 7 is sectional views showing the DRAM structure formed in a wafer of an embodiment preliminarily; and

FIGS. 8A and 8B are sectional views showing a manufacturing process of the DRAM embedded LSI of the embodiment.

### DETAILED DESCRIPTION OF THE INVENTION

Hereinafter, the embodiments of the present invention will be described with reference to the accompanying drawing.

### First Embodiment

A present embodiment concerns a manufacturing method of the DRAM embedded LSI.

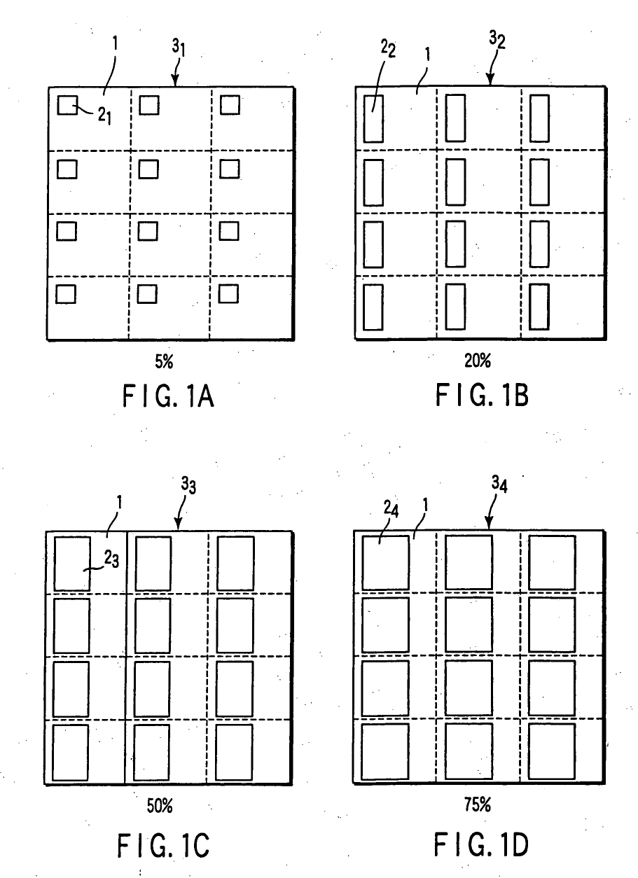

As shown in FIGS. 1A to 1D, wafers 3₁ to 3₄, in which area ratio of DRAM regions 2₁ to 2₄ occupied in a chip region 1 is 5%, 20%, 50%, 75% are prepared preliminarily (step S1).

The memory capacity is increased in the order of DRAM regions 2₁ to 2₄. The memory capacity of each of DRAM regions 2₁ to 2₄ can be changed with the area ratio of the DRAM regions 2₁ to 2₄ equal to each other.

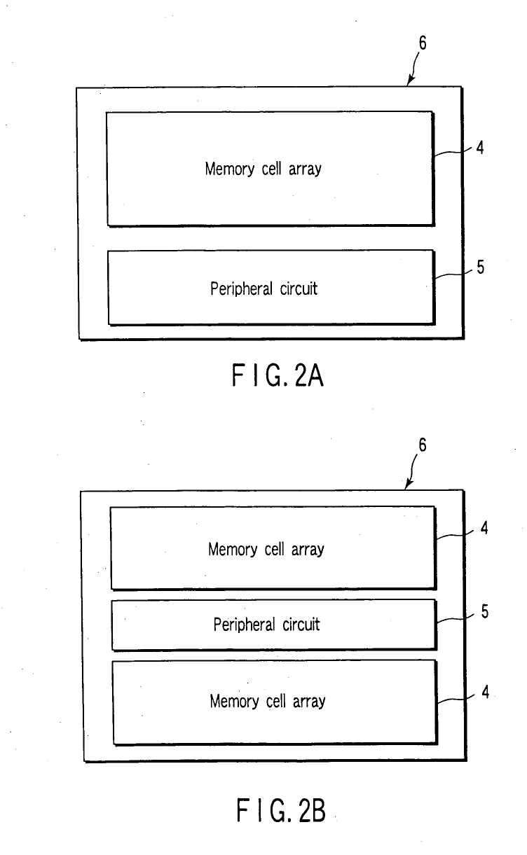

Within the DRAM regions 2₁ to 2₄, as shown in FIGS. 2A and 2B, a DRAM core 6 including a memory cell array 4 and a peripheral circuit 5 for driving it are formed. Although there are some types of the DRAM cores 6, FIGS. 2A and 2B show typical two types. FIG. 2A shows a type comprising a pair of the memory cell arrays 4 and the peripheral circuit 5, and FIG. 2B shows a type in which the memory cell arrays 4 are disposed on and under the peripheral circuit 5.

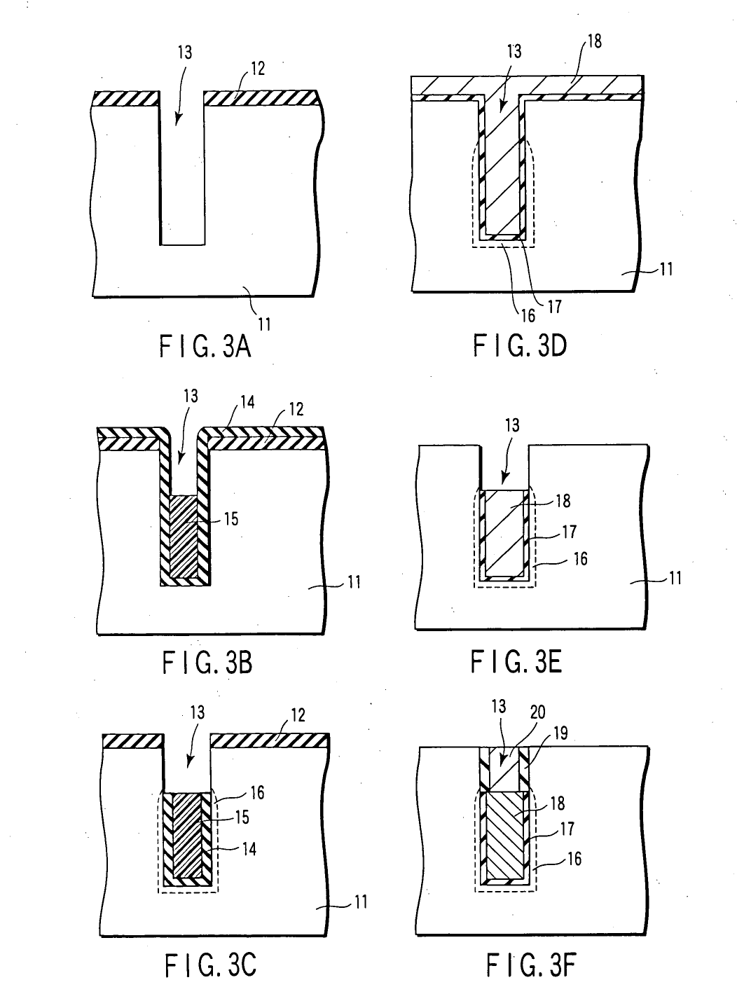

The memory cell array 4 is an integration of so-called 1Tr/1C memory cells each comprising a trench capacitor and a MOS transistor. In the memory cell array 4 here, it is assumed that the process relating to trench capacitor formation indicated in FIGS. 3A to 3F is completed (has been performed).

If the process relating to trench capacitor formation is explained, first, as shown in FIG. 3A, a mask pattern 12 for trench formation is formed on an n type silicon substrate 11 having a (100) orientation and then, the surface of the silicon substrate 11 is etched by reactive ion etching (RIE: Reactive Ion Etching) process using a mask pattern 12 as a mask so as to form a trench 13.

The mask pattern 12 is formed by processing layered insulation films including of silicon oxide film and silicon nitride film formed thereon by photo lithography and etching.

Next, as shown in FIG. 3B, arsenic doped glass film 14 is formed so as to cover the entire side surface and bottom surface of the trench 13 and up to a certain depth of the trench 13 is filled with photo resist 15.

The photo resist 15 is formed as follows. That is, positive type photo resist is coated on the entire surface and next, only the photo resist above a central portion of the trench 13 is exposed to light. Finally, the photo resist is developed and -only that upper portion is removed so as to obtain the photo resist 15.

Next, as shown in FIG. 3C, with the photo resist 15 as a mask, the arsenic doped glass film 14 is etched to expose a side surface of the trench 13 above the photo resist 15. Then, after CVD oxide film is formed entirely, arsenic (n type impurity) in the arsenic doped glass film 14 is diffused into the substrate by heat treatment so as to form n type diffusion layer (plate electrode) 16. The CVD oxide film prevents diffusion of arsenic in the arsenic doped glass film 14 into vapor phase, thereby forming a diffusion layer 16 having a desired density easily.

After that, the mask pattern 12, the arsenic doped glass film 14, the photo resist 15 and the CVD oxide film are removed.

Next, as shown in FIG. 3D, capacitor insulation film 17 is formed entirely to cover the side surface and bottom surface of the trench 13. Then, first polycrystalline silicon film 18 containing impurity such as arsenic which is processed into a first storage node electrode is deposited on an entire surface so as to fill the inside of the trench 13.

Next, as shown in FIG. 3E, the first polycrystalline silicon film 18 is etched back by RIE process so as to form the first storage node electrode 18 and then, the capacitor insulation film 17 is etched using the first storage node electrode 18 as mask, so that the side surface of a portion of the trench 13 above the first storage node electrode 18 is exposed.

Then, as shown in FIG. 3F, collar oxide film (SiO₂ film) 19 is formed on an exposed side wall of the trench 13 and the trench 13 is filled with a second storage node electrode 20 including a second polycrystalline silicon film containing impurity such as arsenic so as to obtain a trench capacitor. The collar oxide film 19 is formed by depositing for example, SiO₂ film on an entire surface and etching the SiO₂ film by RIE process.

Then, the area of the DRAM region occupied in the DRAM embedded LSI is obtained based on a result of circuit design of the DRAM embedded LSI intended to be produced. Next, from wafers prepared preliminarily, one having a DRAM region having an area ratio corresponding to the above-obtained area is selected (step S2).

More specifically, a wafer whose DRAM region is equal to the above-obtained area is selected from the wafers 3 prepared preliminarily indicated in FIGS. 1A to ED or if there is no such wafer, a wafer having a larger DRAM region is selected. In the latter case, usually, a wafer whose DRAM region is nearest the above-obtained area is selected.

According to the present embodiment, the wafer having an area corresponding to an area of the DRAM region of the DRAM embedded LSI which is to be produced is selected from multiple types of wafers whose a layout, pattern and the like of the DRAM region thereof are already determined, designing on the layout and the like of a DRAM region which differs depending on the type of the DRAM embedded LSI becomes unnecessary, thereby making it possible to shorten the design period of the DRAM region.

Because in the DRAM region of the selected wafer 3, as described above, the process relating to trench capacitor formation is preliminarily completed, by executing a remaining conventional process (FIGS. 3G to 3J) of MOS transistors of the memory cell array, the DRAM core in the DRAM region is obtained, and further executing a process of a logic circuit and the like in remaining regions of the logic region, the DRAM embedded LSI is obtained (step S3).

According to the present embodiment, because the process relating to trench capacitor formation is already finished before the layout of the logic region is determined, the manufacturing process after the entire layout including the layout of the logic region is completely determined does not include the process relating to trench capacitor formation.

Therefore, the substantial processing period for the DRAM region can be reduced and consequently, the substantial manufacturing period for the DRAM embedded LSI, i.e., the period after the mask which meets the specifications is formed until the manufacturing process is completed can be reduced. This point will be described in detail later.

FIGS. 3G, 3H a show process of isolation and FIGS. 3I, 3J show processes of MOS transistor and wiring layer. These processes will be described simply.

First, as shown in FIG. 3G, a n-type semiconductor layer 21 is formed on the silicon substrate 11 by, for example, epitaxial growth method and after that, an insulation film 22 is embedded in a shallow trench as shown in FIG. 3H, so as to execute shallow trench isolation (STI). Although FIGS. 3G, 3H indicate isolation of the trench capacitor region, actually, the isolation of other regions is carried out at the same time or separately.

Next, the process of the MOS transistor is performed as shown in FIG. 3I. First, p-type impurity is implanted into the n-type semiconductor layer 21 and silicon substrate 11 and after that, p-type well 23 is formed by annealing. Next, gate oxidation film 24, polycide gate electrode (polycrystalline silicon film 25, tungsten silicide film 26) and insulation film 27 (silicon nitride film) are formed.

Here, the DRAM region and a gate electrode portion (gate oxide film 24, polycide gate electrodes 25, 26 and insulation film 27) are formed in a common process. By forming the DRAM region and the gate electrode portion of the logic region in the common process, the quantity of required processes can be reduced.

Next, as shown in FIG. 3I, source/drain regions 28 are formed by ion implantation and annealing using the gate electrode portion as a mask. Subsequently, a silicon nitride film which is to be processed into an insulation film 29 is formed so as to cover the side wall of the gate and after that, the silicon nitride film is etched by RIE process, and the insulation film 29 is formed. Here, the insulation film 29 is formed so as to cover the surface of the substrate (source/drain regions) between adjacent electrode portions in the DRAM region.

Next, refractory metal film such as titan film, cobalt film is deposited on the entire surface so that the refractory metal film is made to react with the surface of the source/drain regions 28 in the logic region, in order to form a metal silicide film 30.

Because the source/drain regions 28 in the DRAM region is covered with the insulation film 29, no metal silicide film 30 is formed on the source/drain regions 28. Further, because the side wall and top portion of the polycide gate electrodes 25, 26 are covered with the insulation film 29 and the insulation film 27, no metal silicide film 30 is formed on the side wall and top portion of the polycide gate electrodes 25, 26.

Next, the process of the wiring layer is performed as shown in FIG. 3J. First, an interlayer insulation film 31 is formed on an entire surface and a bit line contact (SAC) 32 is formed in the DRAM region while a plug 33 is formed in the logic region. Next, an interlayer insulation film 34 is formed on an entire surface and a bit line 35 is formed in the DRAM region while a metal wire 36 is formed in the logic region. The bit line 35 and the metallic wire 36 are formed of, for example, tungsten. Next, an interlayer insulation film 37 is formed and a plug 38 is formed in the logic region. After that, an interlayer insulation film 39 is formed on an entire surface and a metallic wire 40 is formed. The metal wire 40 is formed of, for example, aluminum.

After that, a completed DRAM embedded LSI is cut out from a selected wafer (step S4).

In the DRAM regions 21 to 24 indicated in FIGS. 1A to 1D, a single trench capacitor region is formed in a chip region 1 of 6 mm×10 mm, for example, and if the chip area of the DRAM embedded LSI intended to produce is the above mentioned value, a single chip region 1 in which the DRAM embedded LSI is formed is cut out from a wafer.

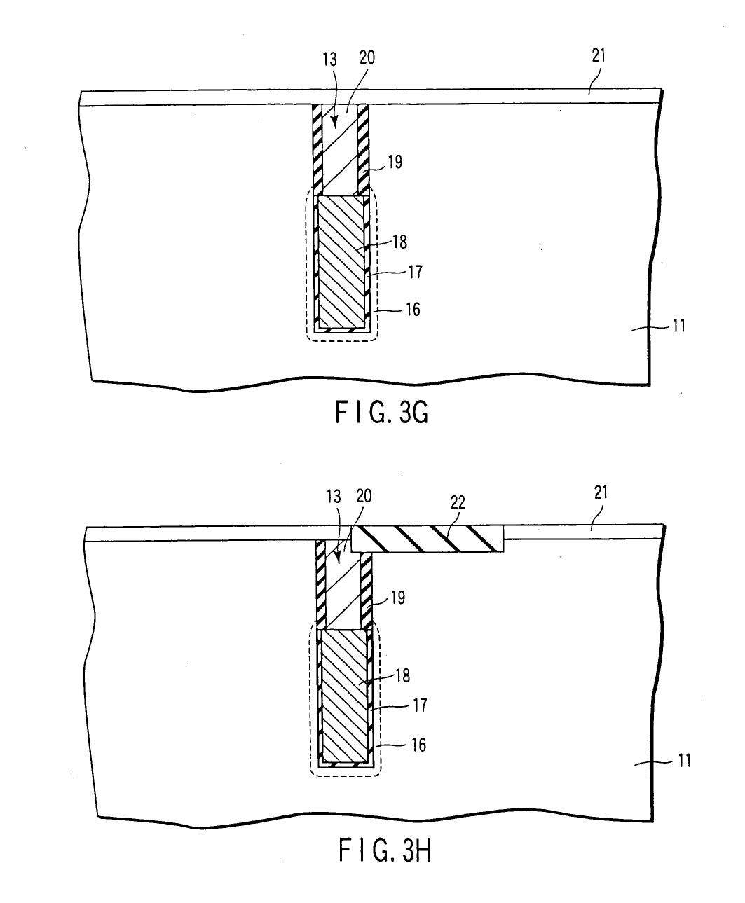

FIG. 4A shows a condition that if the wafer 3 including 5% DRAM region 21, a DRAM embedded LSI 9 produced using a single chip region 1 (basic chip) is cut out from the wafer 3. According to the present embodiment, four DRAM regions 2₁ (a plurality of memory regions having the same structure) each having the same structure are provided on a semiconductor substrate.

The four DRAM regions 2₁ are produced in the same process and basically have the same structure. However, they may have more or less different structure because of a deflection in process. Therefore, according to the present embodiment, even if there is a difference in structure among the four DRAM regions 2₁, it is interpreted that they are the same if it is within a range generated by the deflection in process. Although here the four DRAM regions 2₁ are selected, there is no problem even if two, three or five or more regions are provided.

In the meantime, in FIG. 4A, 7₁ to 7₃ indicate a region including other function than the DRAM (functional region)and for example, 7₂ indicates a logic region including a logic circuit.

On the other hand, if a wider area is required as a DRAM embedded LSI, a plurality of 6 mm×10 mm chip areas in which the DRAM embedded LSIs are formed are cut out from a wafer.

FIG. 4B indicates a condition that if the wafer 3 including 5% DRAM regions 21 is selected, a DRAM embedded LSI 9 manufactured using four chip regions 1 (basic chips) is cut out from the wafer 3. In FIG. 4B, reference numerals 8₁ to 8₁₀ indicate regions (functional regions) having other function than the DRAM, and for example, 8₁₀ indicates a logic region including a logic circuit.

In the meantime, an alignment mark (not shown) is formed at the same position of each chip region 1 and the alignment mark remains on an end product. Thus, if the plurality of chip regions 1 are employed, the same alignment marks are seen at the same positions of each chip region 1 and as a result, it can be confirmed that they are produced according to the method based on the present embodiment.

In the manufacturing process of the DRAM embedded LSI, wafers in which the process relating to trench capacitor formation and plural kinds of the DRAM regions 2 are preliminarily formed are prepared. After the layout and the like are determined completely, if processes after the process relating to trench capacitor formation or the isolation process and subsequent processes are executed, following effect can be obtained in terms of manufacturing period, cost and the like.

Manufacturing of a typical DRAM embedded LSI requires a total raw process time (RPT) of about 450 hours through its entire manufacturing sequence. Of the period, about 150 hours are consumed for formation of the trench capacitor.

As an ordinary method for reducing the RPT, there is a method employing a small batch. In the method, for example, a single lot with 24 wafers is altered into a lot with 12 in order to reduce time required for each process, thereby reducing the RPT.

Although the method is capable of reducing the RPT sufficiently in case of a process carried out using a single type apparatus, it is not capable of reducing so much in case of a process carried out with a batch type apparatus. Thus, if respective processes of the DRAM embedded LSI are carried out all with the single type apparatus, the RPT can be reduced sufficiently by employing the small batch.

However, actually, there is a process using the batch type apparatus, for example, a process for forming the arsenic doped glass film 14 or the first polycrystalline silicon film 18 in the trench 13 (trench filling process). To form the arsenic doped glass film 14 or the like in the trench 13 with an excellent step coverage, it is necessary to reduce sticking coefficient of the source gas which adheres to the side wall of the trench. Thus, film forming process of the arsenic doped glass film 14 or the like is carried out in a reaction controlled region and a process temperature is kept low.

Because in case of film formation under such a low process temperature, the film forming time required for a single wafer is prolonged, the batch type film forming apparatus is employed. In the process carried out with the batch apparatus, plural wafers are processed simultaneously, but the RPT is not reduced so much as described above.

The conventional manufacturing method for the DRAM embedded LSI is incapable of reducing the RPT about a portion inherent of the DRAM even if the method using the small batch is adopted, as long as there is a trench filling process which has to be performed individually if the design of the devices are different in the process relating to trench capacitor formation. As a result, the RPT of the conventional DRAM embedded LSI is determined by the RPT about the portion inherent of the DRAM.

Contrary to this, in case of the manufacturing method of the DRAM embedded LSI of the present embodiment, a manufacturing process after an order is received and a layout design is completed begins with a process subsequent to the process relating to trench capacitor formation (isolation process here), which can be satisfied with only a process necessary for an ordinary logic LSI. Thus, the required manufacturing period is estimated on a condition that the RPT is about 300 hours (about 450 hours usually), thereby leading to a large reduction of the manufacturing period.

Further, because a process after the isolation can be carried out with the single type apparatus without using the batch apparatus, the RPT can be reduced effectively by adopting the small batch method thereby further reducing the manufacturing period.

The trench capacitor process includes a step of forming the trench 13 by RIE process, a step of forming the arsenic doped glass film 14, a step of forming the polycrystalline silicon film 18 (step of filling the trench) and the like. Process conditioning of these steps need to be executed by considering the layout of the trench capacitor occupied in an entire surface and the like.

In an ordinary DRAM embedded LSI, generally, the layout of the DRAM region differs depending on each type. For the reason, the process conditioning for the trench process and the like is carried out for each layout. That is, it takes time to fix the appropriate process out before actual manufacturing of the DRAM embedded LSI. This causes prolonging of total time required for the manufacturing of the DRAM embedded LSI.

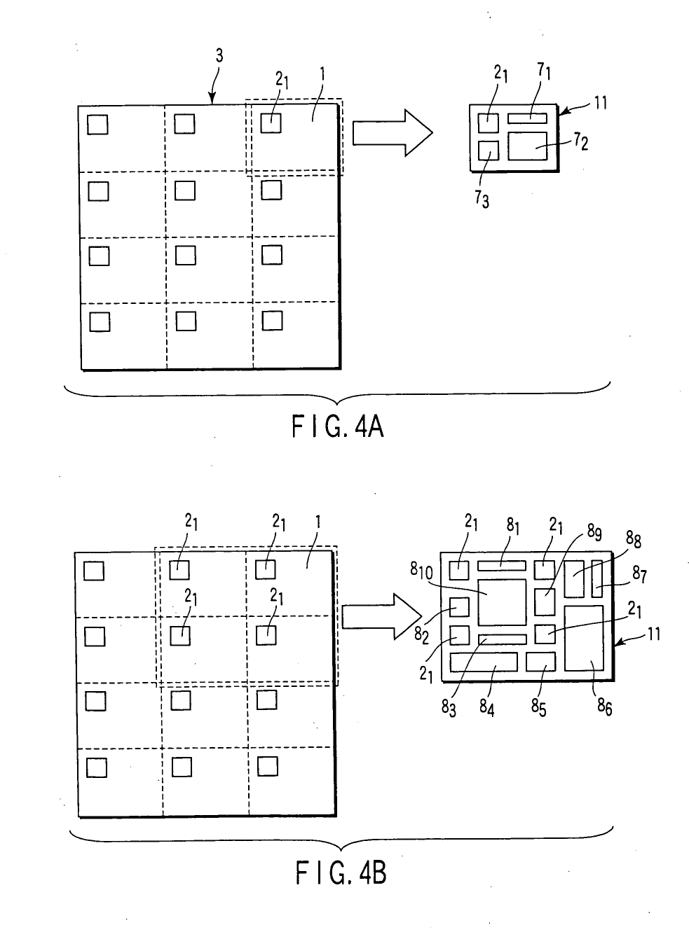

Contrary to this, because the manufacturing method of the DRAM embedded LSI of the present embodiment does not require the process conditioning for each product type, the total process time can be reduced as compared to the conventional manufacturing method of the DRAM embedded LSI (FIG. 6).

On the other hand, because a portion of the mask required for each layout of the DRAM region, which is related to the trench capacitor can be made common, mask cost can be reduced. Further, because the above-mentioned conditioning process can be eliminated, manufacturing cost accompanied by this can be reduced. Therefore, according to the present embodiment, the total manufacturing cost can be reduced as compared to the ordinary manufacturing method of the DRAM embedded LSI.

The production quantity of each type of the DRAM embedded LSI is small and the trench formation process in the trench capacitor formation process differs depending on each product type. Therefore, generally, the trench capacitor formation process of each type of the DRAM embedded LSI is carried out by a different batch processing.

Because in the conventional DRAM embedded LSI process, wafers are supplied under a small lot for each type, the quantity of wafers treated per batch with the batch apparatus is much smaller than the manufacturing capacity of the apparatus so that the availability of the apparatus remains low.

Contrary to this, because the manufacturing method of the present embodiment includes few trench capacitor formation process types (four types in case of FIGS. 1A to 1D), even if a different type DRAM embedded LSI is intended to manufacture, the trench capacitor formation process can be carried out with the same batch even for a different type. Consequently, the quantity of wafers treated per batch with the batch apparatus can be increased thereby leading to the efficient operation of the apparatus.

According to the present embodiment, the layouts for the DRAM region on a wafer shown in FIGS. 1A to 1D are prepared preliminarily. It is desirable to prepare some kinds of easy to use layouts corresponding to the layout of a DRAM embedded LSI scheduled to manufacture.

If the types of the layouts are too few, versatile performance of the prepared layouts is lost. If too many types of the layouts are prepared, many layout types remain not used, thereby increasing waste time and cost. Therefore, it is desirable to prepare appropriate types in only a minimum quantity.

Further, because evaluation of the DRAM region in a prepared wafer is carried out preliminarily, the evaluation on a completed DRAM embedded LSI can be finished more simply than conventionally. Particularly, because the trench capacitor in the DRAM region is evaluated preliminarily about its charge holding function which takes much time, a substantial evaluation time can be reduced.

### Second Embodiment

A present embodiment concerns a manufacturing method of the DRAM embedded LSI.

Like the first embodiment, wafers, in which area ratio of DRAM regions occupied in a chip region is 5%, 20%, 50%, 75% are prepared preliminarily (step S1).

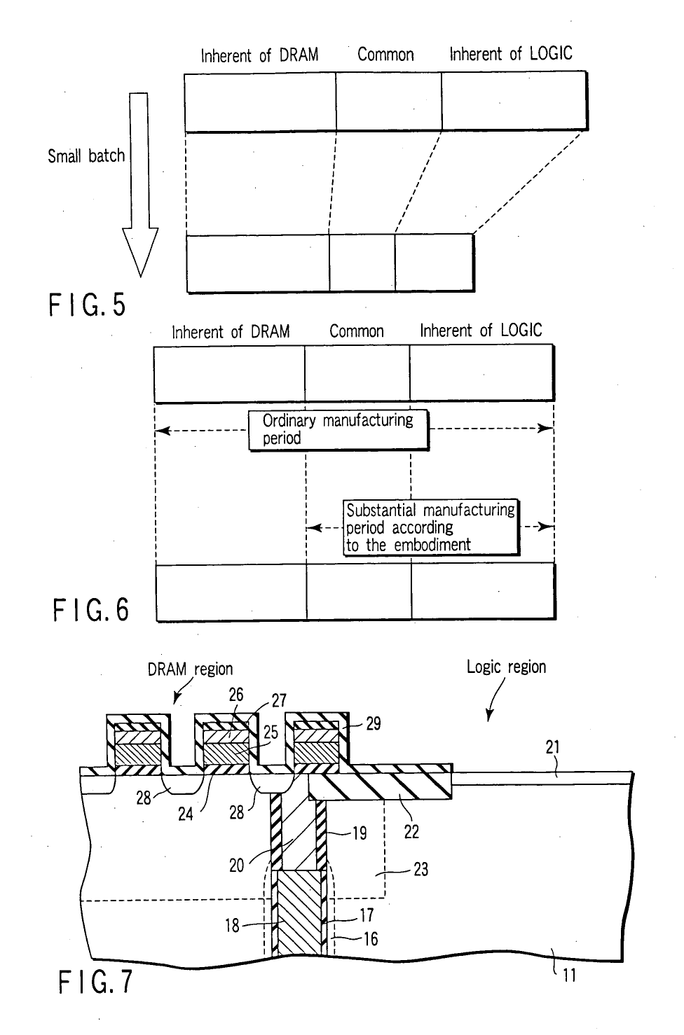

A different point of the present embodiment from the first embodiment is that as shown in FIG. 7, wafer in which not only a process relating to the trench capacitor formation of the DRAM region but also a process for isolation in the DRAM region and a process for formation of the MOS transistor are completed is prepared preliminarily.

The structure shown in FIG. 7 is obtained from a well known process, the structure being explained below.

First, the processes shown in FIGS. 3A to 3H are carried out an subsequently, a region other than the DRAM region is covered with, for example, resist and within the DRAM region, the gate oxide film 24, the polycide gate electrode (polycrystalline silicon film 25, tungsten silicide film 26), the insulation film 27, the source/drain regions 28 and the insulation film 29 are selectively formed. After that, the resist is removed so as to obtain the structure shown in FIG. 7.

Next, the area of the DRAM region occupied in the entire chip of the DRAM embedded LSI is obtained according to a result of the circuit design of a DRAM embedded LSI intended to produce. Next, a wafer having a DRAM region having an area ratio corresponding to the above-obtained area is selected from preliminarily prepared wafers (step S2).

According to the present embodiment, by selecting a wafer fitting to an area of the DRAM region of a DRAM embedded LSI intended to produce from wafers in which a layout, pattern and the like of the DRAM region thereof are already determined, design on the layout and the like of a DRAM region which differs depending on the type of the DRAM embedded LSI becomes unnecessary, thereby making it possible to shorten the design period of the DRAM region.

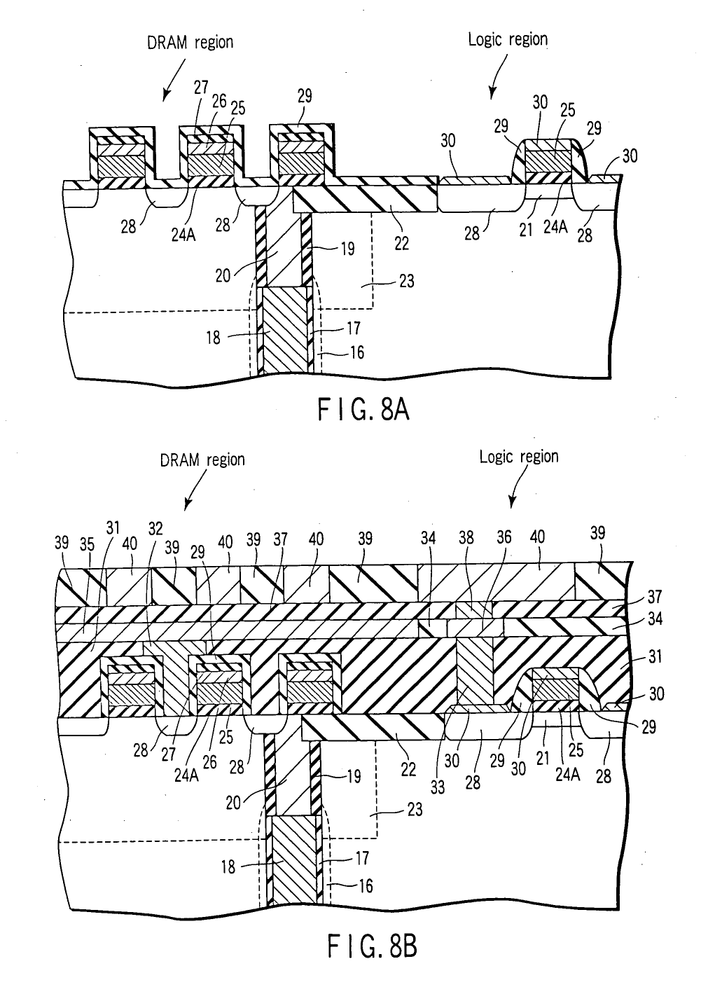

Next, remaining well known processes (FIGS. 8A and 8B) such as MOS transistor formation process in the logic region and isolation region formation process are carried out so as to complete the DRAM embedded LSI (step S3). FIG. 8A is a sectional view after the MOS transistor in the logic region is formed and FIG. 8B is a sectional view after the wiring layer is formed.

After that, the completed DRAM embedded LSI is cut out from the selected wafer (step S4).

The MOS transistor formation process of the present embodiment includes more total steps than an ordinary process of the DRAM embedded LSI. Generally, like the first embodiment, gate electrode portions 24 to 27 in the DRAM region and the logic region are formed in a common process. This aims at achieving reduction of manufacturing period and cost by reducing the quantity of steps.

However, if the process is formed common, a consideration on the process such as silicide block is necessary. This is because the salicide for the MOS transistor in the logic region induces deterioration of the retention characteristic in the MOS transistor in the DRAM region. For the reason, a consideration on the process such as covering the source/drain regions 28 in the DRAM region with the insulation film 29 or the like is necessary so that no silicide is formed like the first embodiment.

This consideration restricts building up of the process such as the layout of the DRAM region and the insulation film 29 (gate side wall insulation film), thereby disabling process integration.

According to the present embodiment, by preparing wafers in which the trench capacitor and gate electrode in the DRAM region are formed preliminarily, the aforementioned consideration on the process is not necessary, so that optimized process integration in the DRAM region and the logic region is enabled. For example, a process which can prevent deterioration of the retention characteristics in the DRAM region and remove an operating speed of the logic region can be achieved.

Although the DRAM region gate electrode may be a gate electrode of a MOS transistor in the memory cell array and peripheral circuit, if it is applied to only the gate electrode of the MOS transistor of the memory cell array, a following effect is obtained.

That is, the MOS transistor of the peripheral circuit can be formed in the same process as the MOS transistor of the logic region, so that the operating speed of the peripheral region is removed thereby achieving a high performance embedded DRAM. Application of the ultra-thin gate oxide (24A in FIGS. 8A and 8B) only to the MOSFET in the logic region is one example.

In case where the MOS transistor of the peripheral circuit is formed through the same process as the MOS transistor in the logic region, a process for isolating the peripheral circuit region of the DRAM region is carried out in step S3.

The manufacturing method of the present embodiment can suppress increase of the manufacturing period which is a problem in the conventional manufacturing method as described below.

As described about the first embodiment, the RPT of a typical DRAM embedded LSI is about 450 hours. However, if the insulation film for isolation and gate electrode portion are formed separately with the DRAM region and the logic region, the RPT is increased to about 500 hours. For the reason, conventionally, the isolation formation process and the gate electrode formation process are performed in a common to avoid an increase of the RPT as mentioned above.

On the other hand, according to the present embodiment, the isolation insulation film and the gate electrode portion are formed separately in the DRAM region and the logic region. Thus, total time consumed for the manufacturing is increased.

However, because a step which needs to be executed actually after a layout is determined is only a step necessary for the logic region processing, if a period after an order is accepted until its delivery is regarded as a manufacturing period, this is completely equal to a period necessary for producing a logic circuit in a logic region, the RPT is about 300 hours. Therefore, the substantial processing period can be reduced thereby achieving a reduction of the manufacturing period.

Although according to the present embodiment, a process until the gate electrode in the DRAM region is formed is handled as a common process regardless of a product type, this division may be changed appropriately as required.

For example, it is permissible that up to the isolation insulation film in the DRAM region is formed and when an entire layout is determined, the device isolation insulation film of the logic region is formed and after that, the gate electrodes of the DRAM region and the logic region are formed in a common process.

According to the above-described method, the depth of the isolation trench for the STI can be changed depending on each region and device breakdown voltage can be changed depending on each region. As a result, an appropriate device breakdown voltage can be applied to each region.

Additionally, the same modification as the first embodiment can be performed. Further, the same effect (not described here) as the first embodiment is obtained.

Although as regards the first and second embodiments, a case where the n-channel type MOS transistor is used as a memory cell has been described, the same effect is obtained if a p-channel type MOS transistor is employed also.

Although as regards the first and second embodiments, a case where the present invention is applied to the DRAM embedded LSI has been described, the present invention can be applied to a memory embedded LSI having other memory also. Further, that memory can be any memory using no trench capacitor.

The first and second embodiments can be applied to a structure in which at least part of a region other than the DRAM (at least a portion of the functional region having other function than the memory) serves as a silicon on insulator (SOI) region.

The structure is realized as follows for instance. Among an SOI substrate (first Si layer/insulation layer/second Si layer), the first Si layer and the insulation layer which are not used as an SOI region are removed, subsequently the second Si layer which is exposed by removing the first Si layer and the insulation layer are used as a seed for Si epitaxial growth, and Si epitaxial layer are grown so as to bury a concave portion which is generated by removing the first Si layer and the insulation layer. With such a structure, the performance of the logic region can be improved without changing the performance and integration level of the DRAM.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-13. (canceled)

14. A method of manufacturing a semiconductor device comprising:
preparing a wafer on which predetermined steps of forming memories have been performed, the wafer including a plurality of memory regions having the same structure,
performing steps subsequent to the predetermined steps of forming the memories on one region of the wafer, the one region including at least one of the plurality of memory regions and forming a functional region having a different function from a memory function on the one region; and
cutting out the one region from the wafer.

15. A method of manufacturing a semiconductor device comprising:
preparing a plurality of wafers on which predetermined steps of forming memories have been performed, the plurality of wafers including a plurality of memory regions respectively, structures of the plurality of memory regions of the plurality of wafers being equal to each other and memory capacities of the plurality of memory regions of the plurality of wafers being different from each other;
selecting one wafer from the plurality of wafers;
performing steps subsequent to the predetermined steps of forming the memories on one region of the selected wafer, the one region including at least one of the plurality of memory regions and forming a region having a different function from a memory function on the one region; and
cutting out the one region from the selected wafer.

16. The method of manufacturing a semiconductor device, according to claim 14, wherein the memory region is a DRAM region including a memory cell array and a peripheral circuit.

17. The method of manufacturing a semiconductor device, according to claim 15, wherein the memory region is a DRAM region including a memory cell array and a peripheral circuit.

18. The method of manufacturing a semiconductor device, according to claim 14, wherein the functional region is a logic region including a logic circuit.

19. The method of manufacturing a semiconductor device, according to claim 15, wherein the functional region is a logic region including a logic circuit.

20. The method of manufacturing a semiconductor device, according to claim 14, wherein the memory region is a DRAM region including a memory cell array, the memory cell array comprising a MOS transistor and a trench capacitor, and the predetermined steps comprising a process of the trench capacitor.

21. The method of manufacturing a semiconductor device, according to claim 15, wherein the memory region is a DRAM region including a memory cell array, the memory cell array comprising a MOS transistor and a trench capacitor, and the predetermined steps comprising a process of the trench capacitor.

22. The method of manufacturing a semiconductor device, according to claim 21, wherein the functional region is a logic region including a logic circuit, the logic circuit comprising a MOS transistor and a gate electrode of the MOS transistor in the DRAM region and a gate electrode of the MOS transistor in the logic region are formed in a common process.

23. The method of manufacturing a semiconductor device, according to claim 22, wherein the DRAM region contains a peripheral circuit, the peripheral circuit comprising a MOS transistor and the MOS transistor of the peripheral circuit and the MOS transistor of the memory cell array are formed in a common process.

24. The method of manufacturing a semiconductor device, according to claim 14, wherein the memory region is a DRAM region including a memory cell array, the memory cell array comprising a MOS transistor and a trench capacitor, and the predetermined step is a formation process of the MOS transistor of the memory cell array.

25. The method of manufacturing a semiconductor device, according to claim 15, wherein the memory region is a DRAM region including a memory cell array, the memory cell array comprising a MOS transistor and a trench capacitor, and the predetermined step is a formation process of the MOS transistor of the memory cell array.

26. The method of manufacturing a semiconductor device, according to claim 24, wherein the functional region is a logic region including a logic circuit, the logic circuit comprising a MOS transistor, a gate electrode of the MOS transistor of the DRAM region and a gate electrode of the MOS transistor of the logic region being formed in separate processes.

27. The method of manufacturing a semiconductor device, according to claim 25, wherein the functional region is a logic region including a logic circuit, the logic circuit comprising a MOS transistor, a gate electrode of the MOS transistor of the DRAM region and a gate electrode of the MOS transistor of the logic region being formed in separate processes.

28. The method of manufacturing a semiconductor device, according to claim 26, wherein the DRAM region contains a peripheral circuit, the peripheral circuit comprising a MOS transistor, the MOS transistor of the peripheral circuit and the MOS transistor of the memory cell array being formed in a common process.

29. The method of manufacturing a semiconductor device, according to claim 27, wherein the DRAM region contains a peripheral circuit, the peripheral circuit comprising a MOS transistor, the MOS transistor of the peripheral circuit and the MOS transistor of the memory cell array being formed in a common process.
